(19) United States
(12) Patent Application Publication
(10) Pub. No.: US 2007/0238619 A1
(43) Pub. Date: Oct. 11, 2007

(54) Superconductor components

(75) Inventor: Xuming Xiong, Niskayuna, NY (US)

Correspondence Address: LARSON NEWMAN ABEL POLANSKY & WHITE, LLP, 5914 WEST COURTYARD DRIVE, SUITE 200, AUSTIN, TX, 78730, US

(73) Assignee: SUPERPOWER, INC., Schenectady, NY (US)

(21) Appl. No.: 11/221,144

(22) Filed: Sep. 6, 2005

(51) Int. Cl. H01L 39/24; H01B 12/00

(52) U.S. Cl. 505/100; 505/237; 505/230

(57) ABSTRACT

A superconductor component is disclosed that includes a metal alloy substrate having a dimension ratio of not less than 10, a compliance layer overlying the substrate, the compliance layer being comprised of an amorphous or nanocrystalline ceramic material having an average grain size not greater than 50 nm, and an IBAD buffer layer overlying the compliance layer. The IBAD buffer layer has a biaxial crystal texture and comprises a material from the group consisting of fluorite type materials, pyrochlore type materials, rare earth C-type materials, non-cubic materials, and layer structured materials. A superconductor layer overlies the IBAD buffer layer

### BACKGROUND

1. Field of the Invention

The present invention generally relates to superconductor components, and in particular, second generation, high-temperature superconductor components (2G HTS components).

2. Description of the Related Art

Superconductor materials have long been known and understood by the technical community. Low-temperature (low-T_{c}) superconductors exhibiting superconductive properties at temperatures requiring use of liquid helium (4.2 K), have been known since about 1911. However, it was not until somewhat recently that oxide-based high-temperature (high-T_{c}) superconductors have been discovered. Around 1986, a first high-temperature superconductor (HTS), having superconductive properties at a temperature above that of liquid nitrogen (77 K) was discovered, namely YBa₂Cu₃O₇₋ₓ (YBCO), followed by development of additional materials over the past 15 years including Bi₂Sr₂Ca₂Cu₃O_{10+y} (BSCCO), and others. The development of high-T_{c} superconductors has brought potential, economically feasible development of superconductor components, incorporating such materials, due partly to the cost of operating such superconductors with liquid nitrogen rather than the comparatively more expensive cryogenic infrastructure based on liquid helium.

Of the myriad of potential applications, the industry has sought to develop use of such materials in the power industry, including applications for power generation, transmission, distribution, and storage. In this regard, it is estimated that the inherent resistance of copper-based commercial power components is responsible for quite significant losses in electricity, and accordingly, the power industry stands to gain significant efficiencies based upon utilization of high-temperature superconductors in power components such as transmission and distribution power cables, generators, transformers, and fault current interrupters. In addition, other benefits of high-temperature superconductors in the power industry include an increase in one to two orders of magnitude of power-handling capacity, significant reduction in the size (i.e., footprint) of electric power equipment, reduced environmental impact, greater safety, and increased capacity over conventional technology. While such potential benefits of high-temperature superconductors remain quite compelling, numerous technical challenges continue to exist in the production and commercialization of high-temperature superconductors on a large scale.

Among the many challenges associated with the commercialization of high-temperature superconductors, many exist around the fabrication of a superconducting tape that can be utilized for formation of various power components. A first generation of superconducting tape includes use of the above-mentioned BSCCO high-temperature superconductor. This material is generally provided in the form of discrete filaments, which are embedded in a matrix of noble metal, typically silver. Although such conductors may be made in extended lengths needed for implementation into the power industry (such as on the order of hundreds of meters), due to materials and manufacturing costs, such tapes do not represent a commercially feasible product.

Accordingly, a great deal of interest has been generated in the so-called second-generation HTS tapes that have superior commercial viability. These tapes typically rely on a layered structure, generally including a flexible substrate that provides mechanical support, at least one buffer layer overlying the substrate, the buffer layer optionally containing multiple films, an HTS layer overlying the buffer film, and an electrical stabilizer layer overlying the superconductor layer, typically formed of at least a noble metal. However, to date, numerous engineering and manufacturing challenges remain prior to full commercialization of such second generation-tapes.

Accordingly, in view of the foregoing, various needs continue to exist in the art of superconductors, and in particular, provision of commercially viable superconducting conductors, methods for forming same, and power components utilizing such superconducting conductors.

### SUMMARY

According to one aspect, a superconductor component is provided that includes a substrate having a dimension ratio of not less than 10, a compliance layer overlying the substrate, the compliance layer being comprised of a ceramic material which is amorphous or nanocrystalline having an average grain size not greater than 50 nm, and an IBAD buffer layer overlying the compliance layer. The IBAD buffer layer has a biaxial crystal texture and comprises a material from the group consisting of fluorite type materials, pyrochlore type materials, rare earth C-type materials, non-cubic structured materials and layer-structured materials. A superconductor layer overlies the IBAD buffer layer.

According to another aspect, a superconductor component is provided that includes a substrate having a dimension ratio of not less than 100, a compliance layer overlying the substrate, the compliance layer being comprised of an amorphous material or a nanocrystalline material having an average grain size not greater than 50 nm, selected from the group consisting of Al₂O₃, Y₂O₃, MgO, ZrO₂, SiO₂, B₂O₃, Sc₂O₃, Cr₂O₃, ReZrO, Re₂O₃ where Re comprises at least one rare earth element (including Sc and Y) and combinations thereof, an IBAD buffer layer overlying the compliance layer, the IBAD buffer layer comprising a material from the group consisting of fluorite type materials and pyrochlore type materials, rare earth C-type materials, non-cubic structured materials, and layer-structured materials. A superconductor layer overlies the IBAD buffer layer.

According to another aspect, a method of forming a superconductor component is provided that includes providing a substrate having a dimension ratio of not less than 10, depositing a compliance layer overlying the substrate at a temperature not greater than 300° C., the compliance layer being amorphous or nanocrystalline having an average grain size not greater than 50 mn. Further, an IBAD buffer layer is deposited to overlie the compliance layer by ion beam assisted deposition, the IBAD buffer layer comprising a material from the group consisting of fluorite type materials, pyrochlore type materials, rare earth C-type materials, non-cubic structured materials, and layer-structured materials. A superconductor layer is deposited to overlie the IBAD buffer layer.

### BRIEF DESCRIPTION OF THE DRAWINGS

FIG. 1 illustrates the general layered structure of a superconductive assembly that is utilized in the fabrication of embodiments of the present invention.

FIGS. 2 and 3 respectively illustrate large scale and local delamination conditions of an HTS conductor.

FIG. 4 and 5 illustrate power cables incorporating conductors according to embodiments of the present invention.

FIG. 6 illustrates a schematic of a power transformer according to an embodiment.

FIG. 7 illustrates a rotating machine according to another embodiment of the present invention.

FIG. 8 illustrates a general schematic of a power grid according to an embodiment of the present invention.

### DESCRIPTION OF THE PREFERRED EMBODIMENT(S)

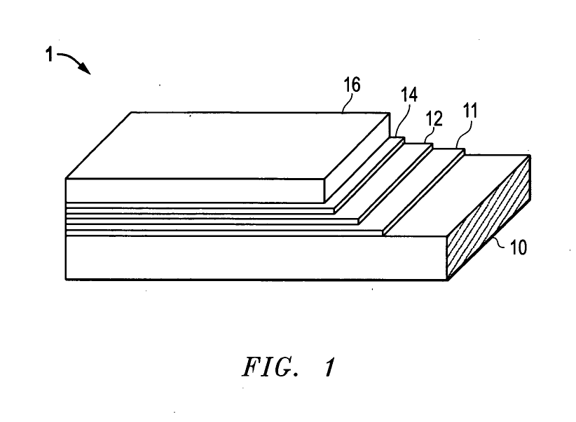

Turning to FIG. 1, the generalized layered structure of a superconductive article according to an embodiment of the present invention is depicted. The superconductive article 1 includes a substrate 10, a compliance layer 11 overlying the substrate 10, a buffer layer 12 overlying the compliance layer 11, a superconductive layer 14, and a stabilizer layer 18, typically a non-noble metal such as copper.

The substrate 10 is generally metal-based, and typically, an alloy of at least two metallic elements. Particularly suitable substrate materials include nickel-based metal alloys such as the known Inconel® group of alloys. The Inconel® alloys tend to have desirable creep, chemical and mechanical properties, including coefficient of expansion, tensile strength, yield strength, and elongation. These metals are generally commercially available in the form of spooled tapes, particularly suitable for superconductive tape fabrication, which typically will utilize reel-to-reel tape handling.

The substrate 10 is typically in a tape-like configuration, having a high dimension ratio. For example, the width of the tape is generally on the order of about 0.4-10 cm, and the length of the tape is typically at least about 100 m, most typically greater than about 500 m. Indeed, embodiments of the present invention provide for superconducting tapes that include substrate 10 having a length on the order of 1 km or above. Accordingly, the substrate may have a dimension ratio which is fairly high, on the order of not less than 10, not less than about 10², or even not less than about 10³. Certain embodiments are longer, having a dimension ratio of 10⁴ and higher. As used herein, the term ‘dimension ratio’ is used to denote the ratio of the length of the substrate or tape to the next longest dimension, the width of the substrate or tape.

In one embodiment, the substrate is treated so as to have desirable surface properties for subsequent deposition of the constituent layers of the superconductive tape. For example, the surface may be lightly polished to a desired flatness and surface roughness. While the substrate may be treated to be biaxially textured as is understood in the art, such as by the known RABiTS (roll assisted biaxially textured substrate) technique, embodiments herein typically utilize a non-textured, polycrystalline substrate, such as commercially available nickel-based tapes noted above.

According to a particular development of embodiments herein a compliance layer 11 is provided to lie between the substrate 10 and the buffer layer 12. Additional details regarding the compliance layer 11 are provided below.

Turning to the buffer layer 12, the buffer layer may be a single layer, or more commonly, be made up of several films. Most typically, the buffer layer includes a biaxially textured film, having a crystalline texture that is generally aligned along crystal axes both in-plane and out-of-plane of the film. Such biaxial texturing may be accomplished by IBAD. As is understood in the art, IBAD is acronym that stands for ion beam assisted deposition, a technique that may be advantageously utilized to form a suitably textured buffer layer for subsequent formation of a superconductive layer having desirable crystallographic orientation for superior superconducting properties. A biaxially textured film has both in-plane and out-of-plane crystal texture, and is defined herein as a polycrystalline material in which both the crystallographic in-plane and out-of-plane grain-to-grain misorientation (mosaic spread) of the topmost surface is less than about 30 degrees, such as less than about 20 degrees, 15 degrees, 10 degrees, or 5 degrees, but is generally finite typically greater than about 1 degree. The degree of biaxial texture can be described by specifying the distribution of grain in-plane and out-of-plane orientations as determined by x-ray diffraction. A full-width-half-maximum (FWHM) of the rocking curve of the out-of-plane (Δθ) and in-plane (Δφ) reflection can be determined. Therefore, the degree of biaxial texture can be defined by specifying the range of Δφ or Δθ for a given sample.

In the art of second generation (2G) high temperature superconductors, IBAD films have generally taken on one of two types of materials, evolutionary texture development films and nucleation texture development films. Nucleation texture development films have generated much interest of late; the typical material of choice is a rock salt or rock salt-like IBAD film, as defined and described in U.S. Pat. No. 6,190,752. Such materials generally are isotropic and have a cubic crystal structure or cubic crystal structure superlattice or backbone. A typical rock salt material of choice is magnesium oxide. Such nucleation development films are deposited quickly and at relatively low thicknesses, on the order or 50 to 500 Angstroms, such as 50 to 200 Angstroms. While nucleation texture films such as rock salt materials have numerous advantages, certain embodiments of the present invention are specifically limited to evolutionary texture development films.

Evolutionary texture development films may also be deposited by IBAD, but unlike nucleation development films, typically require significant thicknesses in order to develop an acceptable biaxial texture having a desirably low mosaic spread. Accordingly, evolutionary texture development films are generally thicker than nucleation development films, having a thickness greater than 100 nm, such as greater than 150 or even 200 nm. Embodiments may have even greater thicknesses such as 300 or 400 nm or greater. Particular embodiments may have an evolutionary texture development film on the order of 500 to 700 nm. Further, certain types of evolutionary texture development films are generally non-isotropic and nbn-cubic unlike rock salt nucleation development films described above. Particular materials include, for example, Al₂O₃, Y₂O₃, MgO, ZrO₂, SiO₂, B₂O₃, Sc₂O₃, Cr₂O₃, ReZrO, and Re₂O₃ where Re comprises at least one rare earth element (including Sc and Y) and combinations thereof. Particular classes of materials that fall within the category of evolutionary texture development films include fluorite type materials such as ZrO₂ (generally fully stabilized, in cubic form) and CeO₂, pyrochlore type materials having the formula RE₂Zr₂O₇, wherein RE is a rare earth element selected from the group consisting of La, Ce, Pr, Nd, Pm, Sm, Eu, Gd, Tb, Dy, Ho, Er, Tm, Yb, Lu with particular examples Eu₂Zr₂O₇ and Gd₂Zr₂O₇, rare earth C-type materials such as Y₂O₃, non-cubic structured materials such as tetragonal crystal structured materials including particularly tetragonal rutile materials (such as TiO₂), and layer-structured materials including deformed perovskite materials and K₂NiF₄-structure materials (including La₂CuO) and Nd₂CuO₄-structure materials. In the particular case of zirconia, typically the zirconia is stabilized so as to be in the cubic structure. While various stabilizing agents may be utilized, yttria is a common stabilizing agent, yttria-stabilized zirconia sometimes referred to by the acronym YSZ.

In the context of the state of the art, evolutionary texture development films formed by IBAD have been employed in second generation HTS conductors. Of particular interest, U.S. Pat. No. 5,872,080 has described a structure in which an IBAD YSZ is deposited to overlie a substrate. U.S. Pat. No. 5,872,080 describes that an intermediate adhesion layer may be present between the substrate and the YSZ layer to improve bonding therebetween, the intermediate layer being formed of a material such as Al₂O₃, CeO₂, Y₂O₃, MgO or polycrystalline YSZ, Al₂O₃ being a preferred material. As described, the intermediate adhesion layer is generally deposited by self-oxidation of a metal alloy substrate containing Al, or high temperature sputter or laser deposition at temperatures greater than about 400° C.

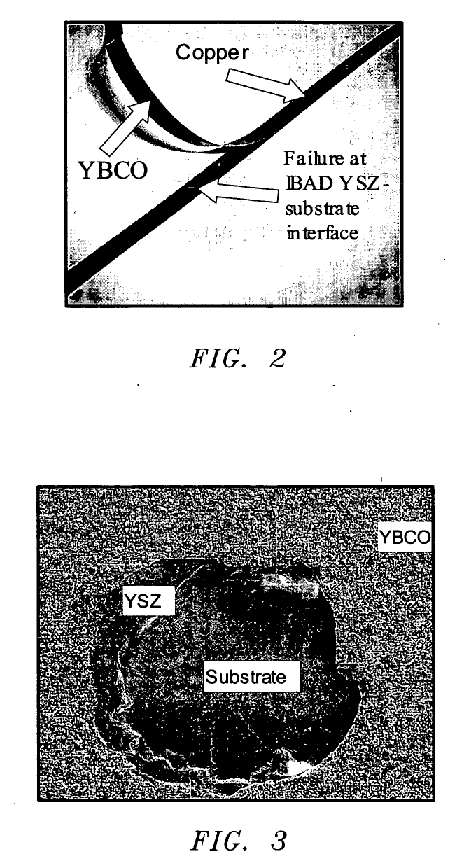

The present inventors have recognized that mechanical robustness of high temperature superconducting articles can be greatly improved by implementation of an intermediate layer that has a compliant nature that further resists mechanical failure of superconducting tapes. This compliance layer is elastic, enabling it to buffer the stress impinging during film processing, to reduce adhesion requirements to metal substrate and prevent the delamination. In this respect, attention is drawn to FIGS. 2 and 3, respectively showing large-scale delamination and local delamination, notably demonstrating failure at the interface between the substrate and the IBAD buffer film.

According to a particular feature, in order to increase the elasticity of the compliance layer, embodiments of the present invention utilize a compliance layer 11 that is amorphous or nanocrystalline, having a microstructure characterized by an average crystal grain size not greater than about 100 nm, such as not greater than 75 nm or 50 nm. Indeed, embodiments may have an average crystal grain size not greater than 30 nm, 20 nm, or 10 nm. Embodiments are based on the concept that the surface or boundary region of a grain is distorted or relaxed and is more elastic than the crystalline regions of the grain, which regions are more rigid and likely to crack under stress. The amorphous film is the extreme of this concept, having no bulk crystallinity. Indeed, according to certain embodiments, the compliance layer 11 may be amorphous, having substantially no defined crystal grains. Usually, the density of such compliance layer is less than the density of the same material having larger crystalline grains (e.g., greater than 1 micron average grain size), the amorphous or nanocrystalline layer having a pore content in the form of finely distributed pores thereby contributing to the compliant/elastic nature.

The present inventors have discovered that while adhesion layers according to the state of the art may improve mechanical integrity, further improvements may be had by utilizing microstructures that provide mechanical compliance so as to absorb handling stresses (e.g., from slitting the tape) and induced stresses and strains (e.g., due to formation techniques, CTE mismatch, or microstructural strains) in the constituent layers of the HTS conductor. In this respect, it has been discovered that use of a compliance layer as described herein may be particularly advantageous in the context of evolutionary texture development films, particularly evolutionary texture development films having substantial thicknesses as described above. In addition, utilization of a compliance layer as described herein may be particularly beneficial in the context of a completed HTS conductor, which generally includes a fairly thick stabilizer layer. In this regard, extensive handling and field testing of second generation HTS conductors complete with stabilizer layer, have a much greater tendency to delaminate than evaluation-only limited length conductors not yet carrying a stabilizer layer. While not wishing to be bound by any particular theory, it is believed that the compliance layer may have a reduced density and/or increased porosity relative to the state of the art adhesion layers, thereby imparting a compliant characteristic between the substrate and the overlying constituent layers of the HTS conductor.

While crystalline and amorphous materials have been utilized in the context of nucleation development of IBAD films such as rock salt films (particularly including MgO), such layers have been generally implemented for prevention of a non-desirable templating effect during growth of the IBAD nucleation development film. In evolutionary texture development films according to embodiments herein, the amorphous or nanocrystalline compliance layer, although similar in form, is different from the amorphous or crystalline seed layer in IBAD MgO type processing, in both function and with respect to the overlying IBAD textured film. The compliance layer functions for anti-delamination purposes and the overlying IBAD textured film is not rock-salt or rock-salt-like material, but comprised of fluorite type material, pyrochlore type material, rare earth C-type material, non-cubic structured material, and layer-structured material. Due perhaps to the attendant relatively large thicknesses of IBAD evolutionary texture development films, use of the compliance layer as described above has particular significance in the context of evolutionary texture development films.

Typically, the compliance layer 11 may be deposited by physical vapor deposition, such as by sputter deposition or evaporation or laser deposition at room temperatures, such as not greater than about 100° C., such as within a range of 10° C. to 100° C. To prevent columnar structure growth and excess porosity (beyond the porosity described above), which affect the elasticity and strength of the compliance layer, optionally irradiation with an energy source, such as ion beam bombardment is used to reduce the porosity and destroy the columnar structure.

An example of deposition of compliance layer on a metal substrate is described as follows. Deposition may be carried out in the same IBAD chamber as for IBAD YSZ or Ga2Zr2O7. This IBAD coating system is equipped with a target setup which can change target without opening vacuum. Al metal target is used to deposit compliance layer alumina on polished metal tape by reactively ion beam sputtering. A 60 cm RF ion source is used to bombard the Al target with ion energy of 1200 eV and ion current of 900 mA. Pure Ar is flowed through the ion source, and O2 is supplied near the tape substrate. Tape is translated from one spool to the other spool at speed of 100 m/h, going through helix winding around a tape holder in deposition area. The tape holder is water cooled. The resulting compliance layer of alumina is amorphous, with thickness of ˜70 nm.

The buffer layer may include additional films in addition to the IBAD film, and as such is sometimes referred to as a buffer stack. The buffer layer may include a barrier film provided to directly contact at least one of and be placed in between the IBAD film and the substrate. In this regard, the barrier film may advantageously be formed of an oxide, such as yttria, and functions to isolate the substrate from the IBAD film. A barrier film may also be formed of non-oxides such as silicon nitride. Suitable techniques for deposition of a barrier film include chemical vapor deposition and physical vapor deposition including sputtering. Typical thicknesses of the barrier film may be within a range of about 100-200 Angstroms. Alternatively, the barrier film may be eliminated, the compliance layer described above having a barrier function. Still further, the buffer layer may also include one or more epitaxially grown films, formed over the IBAD film. In this context, such epitaxially grown films are effective to improve the texture of the IBAD layer, and may desirably be made principally of the same material utilized for the IBAD layer.

In embodiments utilizing certain IBAD films and/or epitaxial films, a lattice mismatch between the IBAD material and the material of the superconductive layer may exist. Accordingly, the buffer layer may further include another buffer film overlying the IBAD film and the epitaxial films (if present), this one in particular implemented to reduce a mismatch in lattice constants between the superconductive layer and the underlying IBAD film and/or epitaxial film. This buffer film may be formed of materials such as CeO₂, Gd₂O₃, LaYO₃, strontium ruthenate, lanthanum manganate, and generally, perovskite-structured ceramic materials. The buffer film may be deposited by various physical vapor deposition techniques.

The superconductive layer 14 is generally in the form of a high-temperature superconductor (HTS) layer. HTS materials are typically chosen from any of the high-temperature superconducting materials that exhibit superconducting properties above the temperature of liquid nitrogen, 77K. Such materials may include, for example, YBa₂Cu₃O₇₋ₓ, Bi₂Sr₂Ca₂Cu₃O_{10+y}, Tl₂Ba₂Ca₂Cu₃O_{10+y}, and HgBa₂ Ca₂Cu₃ O_{8+y}. One class of materials includes REBa₂Cu₃O₇₋ₓ, wherein RE is a rare earth element. Of the foregoing, YBa₂Cu₃O₇₋ₓ, also generally referred to as YBCO, may be advantageously utilized. The superconductive layer 14 may be formed by any one of various techniques, including thick and thin film forming techniques. Preferably, a thin film physical vapor deposition technique such as pulsed laser deposition (PLD) can be used for a high deposition rates, or a chemical vapor deposition technique can be used for lower cost and larger surface area treatment. Typically, the superconductive layer has a thickness on the order of about 1 to about 30 microns, most typically about 2 to about 20 microns, such as about 2 to about 10 microns, in order to get desirable amperage ratings associated with the superconductive layer 14.

The stabilizer layer 16 is generally implemented to provide a low resistance interface and for electrical stabilization to aid in prevention of superconductor burnout in practical use. More stabilizer layer 16 aids in continued flow of electrical charges along the superconductor in cases where cooling fails or the critical current density is exceeded, and the superconductive layer moves from the superconducting state and becomes resistive. In one embodiment, the stabilizer layer includes a noble metal film in direct contact with the superconductive layer 14 to prevent unwanted interaction between films of the stabilizer layer and the superconductive layer 14, and a non-noble metal film (e.g., copper or aluminum) for current carrying capability overlying the noble metal film. Typical noble metals include gold, silver, platinum, and palladium. Silver is typically used due to its cost and general accessibility. The noble metal film is typically made to be thick enough to prevent unwanted diffusion of the components from the stabilizer layer 16 into the superconductive layer 14, but is made to be generally thin for cost reasons (raw material and processing costs). Typical thicknesses of the noble metal film range within about 0.1 to about 10.0 microns, such as 0.5 to about 5.0 microns. Various techniques may be used for deposition of noble metals, including physical vapor deposition, such as DC magnetron sputtering.

Alternatively, the noble metal film may not be included in the stabilizer layer, with the non-noble metal film directly in contact with the superconductive layer 14. This approach has been shown to work in cases where the non-noble film is deposited by a low temperature technique to prevent unwanted interaction between the stabilizer layer 16 and the superconductive layer 14.

The stabilizer layer 16 functions as a protection/shunt layer to enhance stability against harsh environmental conditions and superconductivity quench. The layer is generally dense and thermally and electrically conductive, and functions to bypass electrical current in case of failure of the superconducting layer. It may be formed by any one of various thick and thin film forming techniques, such as by laminating a pre-formed copper strip onto the superconducting tape, by using an intermediary bonding material such as a solder or flux. Other techniques have focused on physical vapor deposition, typically evaporation or sputtering, as well as wet chemical processing such as electro-less plating, and electroplating.

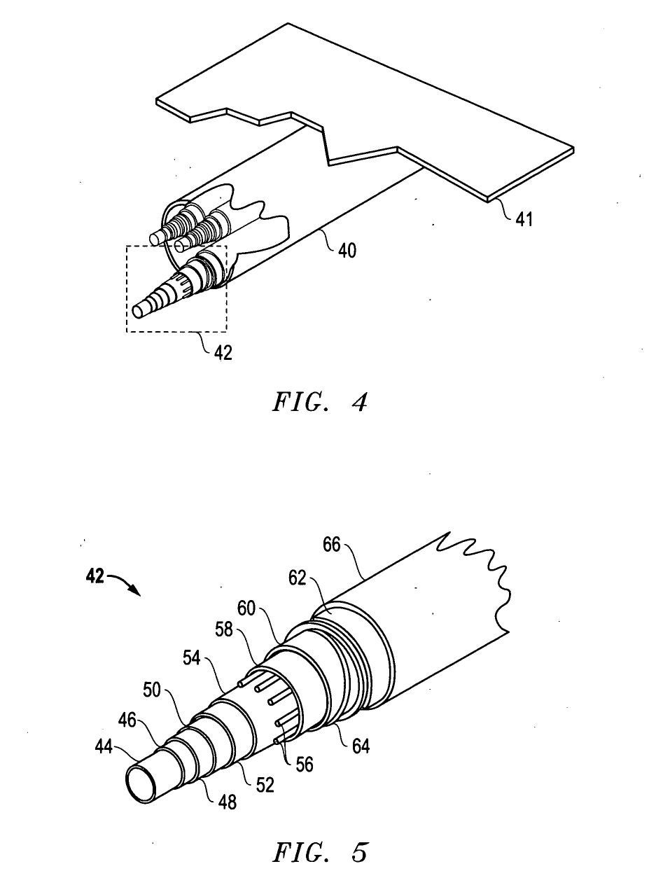

Moving away from the particular structure of the superconducting tape, FIGS. 4 and 5 illustrate implementation of a superconducting conductor in a commercial power component, namely a power cable. FIG. 4 illustrates several power cables 42 extending through an underground conduit 40, which may be a plastic or steel conduit. FIG. 4 also illustrates the ground 41 for clarity. As is shown, several power cables may be run through the conduit 40.

Turning to FIG. 5, a particular structure of a power cable is illustrated. In order to provide cooling to maintain the superconductive power cable in a superconducting state, liquid nitrogen is fed through the power cable through LN2 duct 44. One or a plurality of HTS conductors 46 is/are provided so as to cover the duct 44. While conventional tapes are generally placed onto the duct 44 in a helical manner, the conductors according to embodiments of the present invention need not be helically wound, but, in other embodiments, may extend linearly, parallel to the longitudinal axis of the power cable. Further components include a copper shield 48, a dielectric tape 50 for dielectric separation of the components, a second HTS tape 52, a copper shield 54 having a plurality of centering wires 56, a second, larger LN2 duct 58, thermal insulation 60, provided to aid in maintaining a cryogenic state, a corrugated steel pipe 62 for structural support, including skid wires 64, and an outer enclosure 66.

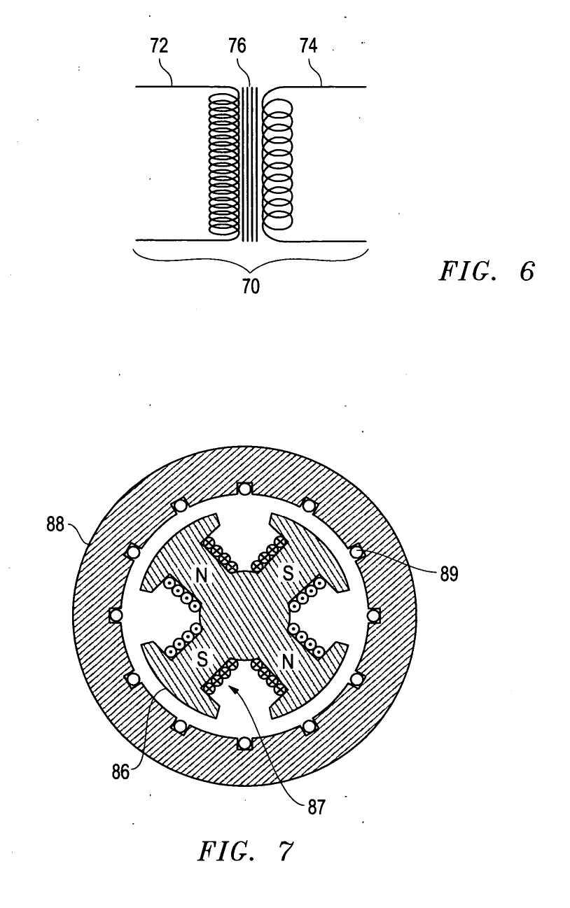

FIG. 6 illustrates schematically a power transformer having a central core 76 around which a primary winding 72 and a secondary winding 74 are provided. It is noted that FIG. 6 is schematic in nature, and the actual geometric configuration of the transformer may vary as is well understood in the art. However, the transformer includes at least the basic primary and secondary windings. In this regard, in the embodiment shown in FIG. 6, the primary winding has a higher number of coils than the secondary winding 74, representing a step-down transformer that reduces voltage of an incoming power signal. In reverse, provision of a fewer number of coils in the primary winding relative to the secondary winding provides a voltage step-up. In this regard, typically step-up transformers are utilized in power transmission substations to increase voltage to high voltages to reduce power losses over long distances, while step-down transformers are integrated into distribution substations for later stage distribution of power to end users. At least one of and preferably both the primary and secondary windings comprise superconductive conductors in accordance with the foregoing description

Turning to FIG. 7, the basic structure of a generator is provided. The generator includes a rotor 86 that is driven as is known in the art, such as by a turbine. Rotor 86 includes high-intensity electromagnets, which are formed of rotor coils 87 that form the desired electromagnetic field for power generation. The generation of the electromagnetic field generates power in the stator 88, which comprises at least one conductive winding 89. According to a particular feature of the embodiment, the rotor coils and/or the stator winding comprises a superconductive conductor in accordance with embodiments described above. Low loss superconductors used in the stator windings generally substantially reduce hysteresis losses.

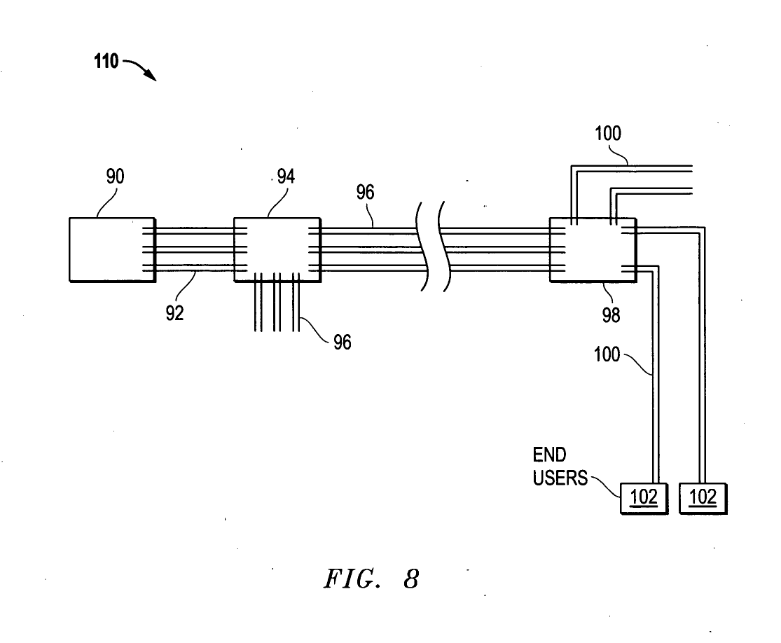

Turning to FIG. 8, a basic schematic of a power grid is provided. Fundamentally, the power grid 110 includes a power plant 90 typically housing a plurality of power generators. The power plant 90 is electrically connected and typically co-located with a transmission substation 94. The transmission substation contains generally a bank of step-up power transformers, which are utilized to step-up voltage of the generated power. Typically, power is generated at a voltage level on the order of thousands of volts, and the transmission substation functions to step-up voltages are on the order of 100,000 to 1,000,000 volts in order to reduce line losses. Typical transmission distances are on the order of 50 to 1,000 miles, and power is carried along those distances by power transmission cables 96. The power transmission cables 96 are routed to a plurality of power substations 98 (only one shown in FIG. 8). The power substations contain generally a bank of step-down power transformers, to reduce the transmission level voltage from the relatively high values to distribution voltages, typically less than about 10,000 volts. A plurality of further power substations may also be located in a grid-like fashion, provided in localized areas for localized power distribution to end users. However, for simplicity, only a single power substation is shown, noting that downstream power substations may be provided in series. The distribution level power is then transmitted along power distribution cables 100 to end users 102, which include commercial end users as well as residential end users. It is also noted that individual transformers may be locally provided for individual or groups of end users. According to a particular feature, at least one of the generators provided in the power plant 90, the transformers and the transmission substation, the power transmission cables, the transformers provided in the power substation, and the power distribution cables contain superconductive tapes in accordance with the present description.

### EXAMPLES

A Hastelloy C metal alloy substrate in the form of a tape having a thickness of ˜0.05 mm, length 250 m was polished to surface roughness of 1-5 nm Ra, then amorphous alumina of ˜70 nm was deposited on the metal alloy substrate by reactive ion beam sputtering of an Al metal target in a vacuum chamber at room temperature. During deposition, the tape translates from a feed spool, through a deposition zone in the form of a helix winding to make full use of large deposition area, then to a take-up spool. The Al target is then changed to a YSZ target, and sharply textured YSZ of ˜1000 nm is deposited on the amorphous alumina coated substrate by ion-beam assisted deposition (IBAD). The a lattice-match layer of CeO₂ of ˜20 nm in thickness is grown epitaxially on the biaxially-textured YSZ by sputter or PLD method at high temperature, the YBCO superconducting film of 1-3 microns is deposited on the top of CeO₂ by MOCVD. Then the tape is coated with silver of about 2-3 microns by DC sputtering, and then the tape is coated with about 20 microns of Cu on both sides of tape as a stabilizer.

While the invention has been illustrated and described in the context of specific embodiments, it is not intended to be limited to the details shown, since various modifications and substitutions can be made without departing in any way from the scope of the present invention. For example, additional or equivalent substitutes can be provided and additional or equivalent production steps can be employed. As such, further modifications and equivalents of the invention herein disclosed may occur to persons skilled in the art using no more than routine experimentation, and all such modifications and equivalents are believed to be within the scope of the invention as defined by the following claims.

1. A superconductor component comprising:
a metal alloy substrate having a dimension ratio of not less than 10;
a compliance layer overlying the substrate, the compliance layer being comprised of a ceramic material which is amorphous or nanocrystalline having an average grain size not greater than 50 nm;
an IBAD buffer layer overlying the compliance layer, the IBAD buffer layer having a biaxial crystal texture and comprising a material from the group consisting of fluorite type materials, pyrochlore type materials, rare earth C-type materials, non-cubic structured materials, and layer-structured materials; and
a superconductor layer overlying the IBAD buffer layer.

2. The superconductor component of claim 1, wherein the compliance layer has an average grain size not greater than 40 nm.

3. The superconductor component of claim 1, wherein the compliance layer has an average grain size not greater than 30 nm.

4. (canceled)

5. The superconductor component of claim 1, wherein the compliance layer in untextured.

6. The superconductor component of claim 1, wherein the IBAD buffer layer comprises a fluorite-type material, from the group consisting of fully stabilized-ZrO₂, CeO₂.

7. The superconductor component of claim 1, wherein the IBAD buffer layer comprises a pyrochlore type having the formula RE₂Zr₂O₇, wherein RE is a rare earth element selected from the group consisting of La, Ce, Pr, Nd, Pm, Sm, Eu, Gd, Tb, Dy, Ho, Er, Tm, Yb, Lu.

8. The superconductor component of claim 1, wherein the IBAD buffer layer comprises a rare earth C-type material.

9. The superconductor component of claim 8, wherein the IBAD buffer layer comprises Y₂O₃

10. The superconductor component of claim 1, wherein the IBAD buffer layer comprises a non-cubic structured material having a tetragonal structure.

11. (canceled)

12. (canceled)

13. The superconductor component of claim 1, wherein the IBAD buffer layer comprises layer-structured material.

14. The superconductor component of claim 13, wherein the layer-structured material comprises material with K₂NiF₄ structure.

15. (canceled)

16. The superconductor component of claim 13, wherein the IBAD buffer layer comprises material with Nd₂CuO₄-structure.

17. (canceled)

18. The superconductor component of claim 1, wherein the IBAD buffer layer has a thickness not less than about 100 nm.

19. (canceled)

20. (canceled)

21. The superconductor component of claim 1, wherein the compliance layer comprises a material from the group consisting of Al₂O₃, Y₂O₃, MgO, ZrO₂, SiO₂, B₂O₃, Sc₂O₃, Cr₂O₃, ReZrO, Re₂O₃ where Re comprises at least one rare earth element (including Sc and Y) and combinations thereof.

22. The superconductor component of claim 21, wherein the compliance layer comprises Al₂O₃, wherein the Al₂O₃ is predominantly amorphous.

23. The superconductor component of claim 21, wherein the compliance layer comprises stabilized ZrO₂, the stabilized ZrO₂ is predominantly nanocrystalline yttria stabilized ZrO₂ having an average grain size not greater than 20 nm.

24. (canceled)

25. The superconductor component of claim 1, further comprising a stabilizer layer overlying the superconductor layer, the stabilizer layer comprising a conductive metal.

26. (canceled)

27. (canceled)

28. The superconductor component of claim 1, wherein the component is a power cable, the power cable including a plurality of conductors, each conductor comprising said substrate, said compliance layer, said IBAD buffer layer, and said superconductor layer.

29. A superconductor component comprising:
a metal alloy substrate having a dimension ratio of not less than 100;
a compliance layer overlying the substrate, the compliance layer being comprised of an amorphous material or a nanocrystalline material having an average grain size not greater than 50 nm, selected from the group consisting of Al₂O₃, Y₂O₃, MgO, ZrO₂, SiO₂, B₂O₃, Sc₂O₃, Cr₂O₃, ReZrO, Re₂O₃ where Re comprises at least one rare earth element (including Sc and Y) and combinations thereof;
an IBAD buffer layer overlying the compliance layer, the IBAD buffer layer comprising a material from the group consisting of fluorite type materials and pyrochlore type materials, rare earth C-type materials, non-cubic structured materials, and layer-structured materials; and
a superconductor layer overlying the IBAD buffer layer.

30. The superconductor component of claim 29, wherein the IBAD buffer layer is selected from the group consisting of yttria stabilized ZrO₂ and Gd₂Zr₂O₇.

31. (canceled)

32. (canceled)

33. (canceled)
